(19) United States
(12) Patent Application Publication
(10) Pub. No.: US 2009/0091892 A1
(43) Pub. Date: Apr. 9, 2009

(54) Semiconductor Device

(75) Inventors: Takukazu Otsuka, Kyoto-shi (JP); Keiji Okumura, Kyoto-shi (JP); Masao Saito, Kyoto-shi (JP)

Correspondence Address: FISH & RICHARDSON P.C., P.O. BOX 1022, MINNEAPOLIS, MN, 55440-1022, US

(73) Assignee: Rohm Co., Ltd., Kyoto-fu (JP)

(21) Appl. No.: 12/234,771

(22) Filed: Sep. 22, 2008

(30) Foreign Application Priority Data
Sep. 26, 2007 (JP) 2007-249491
Jan. 31, 2008 (JP) 2008-021890

(51) Int. Cl. H05K 7/20

(52) U.S. Cl. 361/715

(57) ABSTRACT

A semiconductor device includes: a first output unit configured to output a first phase; a second output unit configured to output a second phase different from the first phase, the second output unit being disposed on a plane intersecting with a plane having the first output unit disposed thereon; and a controller configured to control the output units.

### CROSS REFERENCE TO RELATED APPLICATIONS AND INCORPORATION BY REFERENCE

This application is based upon and claims the benefit of priority from prior Japanese Patent Application P2007-249491 filed on Sep. 26, 2007 and P2008-021890 filed on Jan. 31, 2008; the entire contents of which are incorporated by reference herein.

### BACKGROUND OF THE INVENTION

1. Field of the Invention

The present invention relates to a semiconductor device that is an intelligent power module including a power device and a control circuit.

Moreover, the present invention relates to a semiconductor device including a plurality of switching devices to be switched on and off at different frequencies.

2. Description of the Related Art

There has heretofore been known an IPM that is a power module in which a power device including an IGBT and the like and a control circuit for controlling a gate and the like of the IGBT are integrally provided.

Japanese Patent Application Publication No. 2005-142228 (hereinafter Patent Document 1) discloses an IPM in which power devices (output units) for respectively outputting a U-phase, a V-phase and a W-phase are arranged on one flat-plate module bottom.

Moreover, there has been known a semiconductor device such as a power module which outputs a plurality of different phases (see, for example, Patent Document 1).

Such a semiconductor device includes: a plurality of output units configured to respectively output different phases; a booster configured to boost power supplied from an external power source; and a controller configured to control the output units and the booster. Each of the output units and the booster normally includes at least two switching devices. Each of the switching devices is controlled by the controller so as to be switched on and off at a predetermined frequency.

However, the IPM disclosed in Patent Document 1 has a problem of an increased plane area since the power devices are provided on one planar module bottom.

Moreover, in the semiconductor device described above, different frequencies are respectively used for switching on and off the switching devices provided in the units. Thus, there is a problem of temperature rise of the switching device having a high frequency.

### SUMMARY OF THE INVENTION

The present invention was made to solve the problems described above, and aims to provide a semiconductor device whose plane area can be reduced.

Moreover, the present invention was made to solve the problems described above, and aims to provide a semiconductor device capable of suppressing temperature rise of a switching device having a high frequency.

As one aspect of the present invention, a semiconductor device includes: a first output unit configured to output a first phase; a second output unit configured to output a second phase different from the first phase, the second output unit being disposed on a plane intersecting with a plane having the first output unit disposed thereon; and a controller configured to control the first and second output units.

As another aspect of the present invention, the plane having the first output unit disposed thereon and the plane having the second output unit disposed thereon are different planes of a polyhedron.

As another aspect of the present invention, a plane having the controller disposed thereon is any one of the planes of the polyhedron, which is different from the plane having the first output unit disposed thereon and the plane having the second output unit disposed thereon.

As another aspect of the present invention, each of the first output unit and the second output unit includes a radiator plate, and the first output unit and the second output unit are configured so that the radiator plates are disposed on inner sides.

As another aspect of the present invention, each of the first output unit and the second output unit include radiator plates, and the first output unit and the second output unit are configured so that the radiator plates are disposed on outer sides.

As another aspect of the present invention, the plane having the first output unit disposed thereon and the plane having the second output unit disposed thereon are two different planes of a bent plate member.

As another aspect of the present invention, the first output unit is provided upright on the controller.

As another aspect of the present invention, the first output unit includes control bus bars for connection to the controller, and the control bus bars are inserted into holes formed in the controller.

As another aspect of the present invention, each of the first output unit and the second output unit includes a radiator plate for conducting heat in a direction different from a direction in which the controller is disposed.

As another aspect of the present invention, each of the first output unit and the second output unit includes a first bus bar through which a current flows in a first direction and a second bus bar through which a current flows in a second direction opposite to the first direction, and the first bus bar of the first output unit is disposed at a position closer to the second bus bar of the second output unit than the first bus bar of the second output unit.

As another aspect of the present invention, the first output unit and the second output unit share a first bus bar through which a current flows in a first direction and also share a second bus bar through which a current flows in a second direction opposite to the first direction, and the first bus bar and the second bus bar are stacked with an insulating member interposed therebetween.

As another aspect of the present invention, the first output unit includes a plurality of semiconductor elements and a wiring board having the semiconductor elements provided thereon, and the plurality of semiconductor elements are disposed on both sides of the board.

As another aspect of the present invention, a semiconductor device includes: a plurality of output units each having switching devices and configured to output different phases, respectively; and a voltage regulator having switching devices and configured to regulate a voltage applied from the outside. The semiconductor device is formed in a hollow structure having a plurality of sides on which the output units and the voltage regulator are disposed. The switching devices include a first switching device to be switched on and off at a first frequency and a second switching device to be switched on and off at a second frequency higher than the first frequency, and the second switching device is disposed upstream of the first switching device in an air flow.

As another aspect of the present invention, the voltage regulator includes a high voltage unit having the first switching device and a low voltage unit to which a voltage lower than that applied to the high voltage unit is applied, the low voltage unit being disposed on the same side as the high voltage unit and having the second switching device.

As another aspect of the present invention, any of the output units is disposed on the same side as the voltage regulator and has the first switching device, and the voltage regulator has the second switching device.

The semiconductor device of the present invention can reduce a plane area by arranging the two output units configured to output different phases on the different planes intersecting with each other.

Moreover, according to the present invention, the second frequency for switching on and off the second switching device is higher than the first frequency for switching on and off the first switching device. Specifically, a heating value of the second switching device is larger than that of the first switching device. Here, in the present invention, the second switching device is disposed on an upstream side of the first switching device in the air flow. Therefore, heat transmission from the first switching device to the second switching device can be suppressed. As a result, temperature rise of the second switching device can be suppressed.

### BRIEF DESCRIPTION OF THE DRAWINGS

FIG. 1 is an overall perspective view of an IPM according to a first embodiment.

FIG. 2 is a cross-sectional view along the line II-II in FIG. 1.

FIG. 3 is a cross-sectional view along the line III-III in FIG. 1.

FIG. 4 is a plan view of a U-phase output unit.

FIG. 5 is a cross-sectional view along the line V-V in FIG. 4.

FIG. 6 is a perspective view showing a switching device.

FIG. 7 is a perspective view showing a diode.

FIG. 8 is a schematic circuit diagram of the IPM.

FIG. 9 is a perspective view showing a step of assembling the IPM.

FIG. 10 is a perspective view showing a step of assembling the IPM.

FIG. 11 is a perspective view showing a step of assembling the IPM.

FIG. 12 is a cross-sectional view equivalent to FIG. 2, showing an IPM according to a second embodiment.

FIG. 13 is a cross-sectional view equivalent to FIG. 2, showing an IPM according to a third embodiment.

FIG. 14 is a cross-sectional view of an IPM according to a fourth embodiment.

FIG. 15 is a view before a step of bending the IPM according to the fourth embodiment.

FIG. 16 is a perspective view showing a case and bus bars according to a fifth embodiment.

FIG. 17 is a perspective view showing a case and bus bars according to a sixth embodiment.

FIG. 18 is a cross-sectional view along the line X-X in FIG. 17.

FIG. 19 is an overall perspective view of a power module according to a seventh embodiment.

FIG. 20 is a plan view of a U-phase output unit.

FIG. 21 is a plan view of a booster.

FIG. 22 is a circuit diagram of the power module.

FIG. 23 is a perspective view of a switching device.

FIG. 24 is a perspective view of a diode.

FIG. 25 is a graph showing an experimental result on temperature rise of the power module.

FIG. 26 is an overall perspective view of a power module according to an eighth embodiment.

### DETAILED DESCRIPTION OF THE INVENTION

### First Embodiment

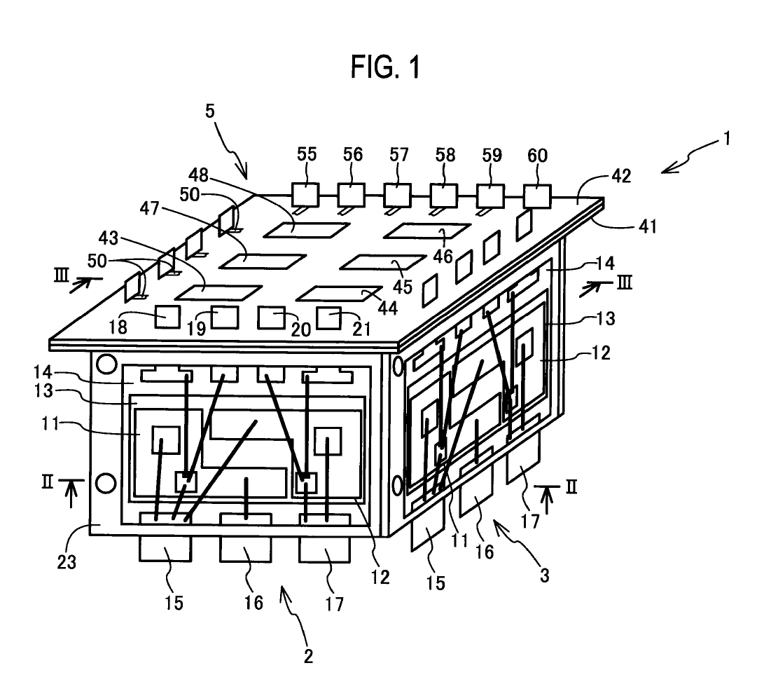

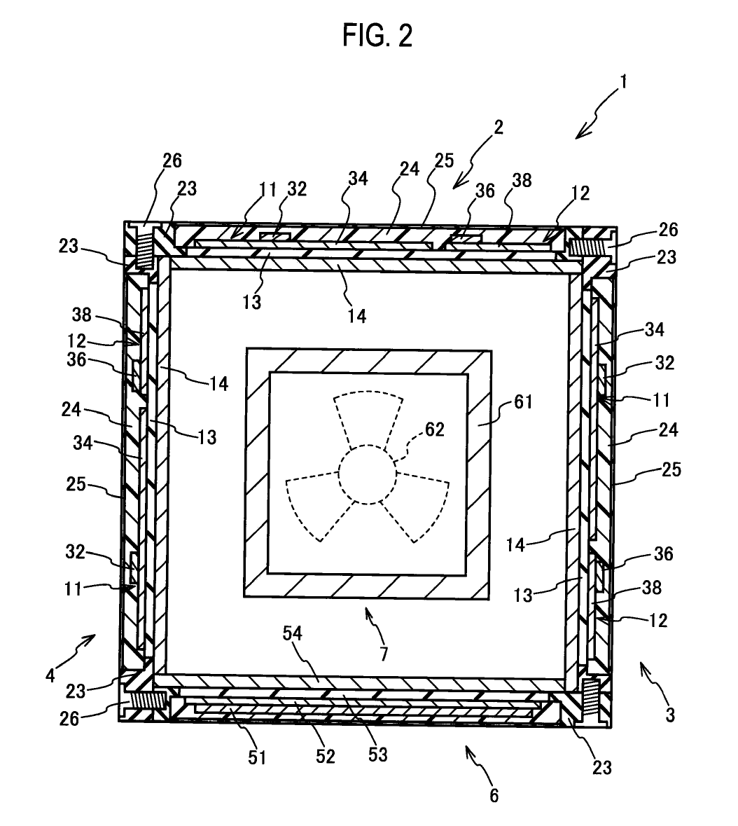

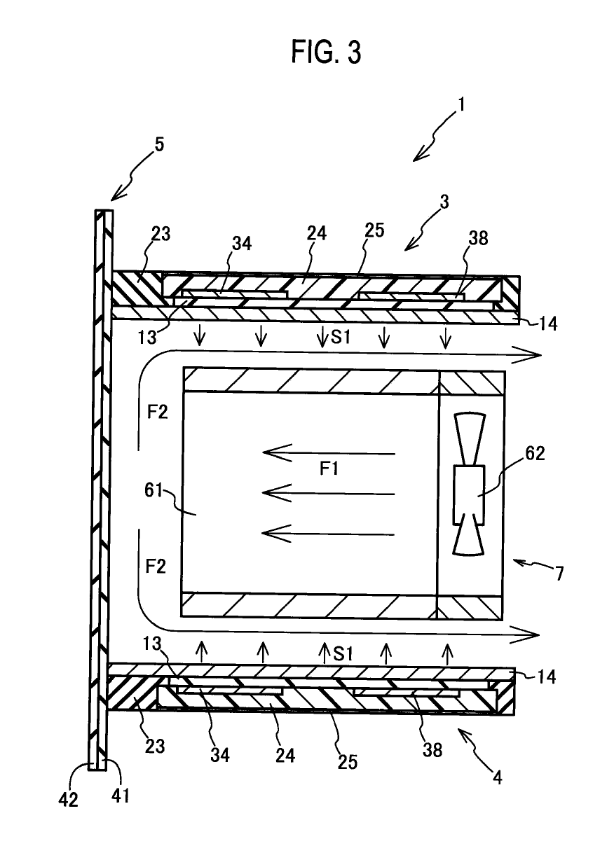

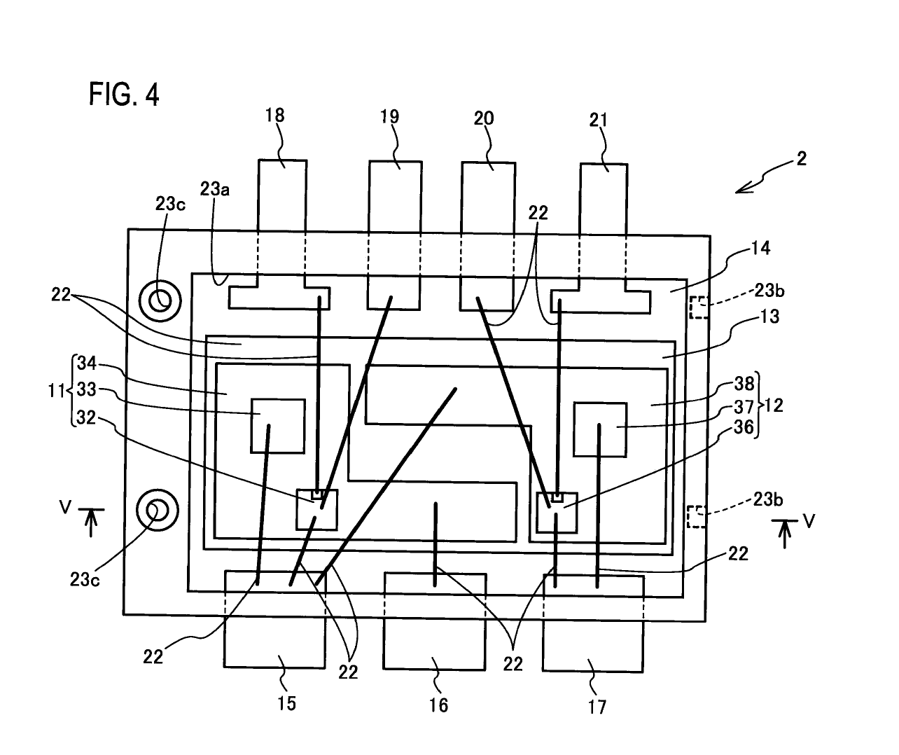

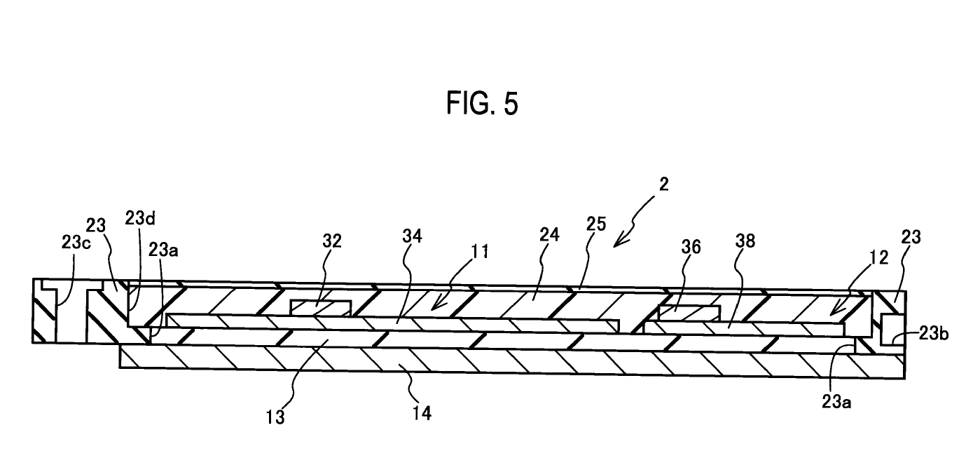

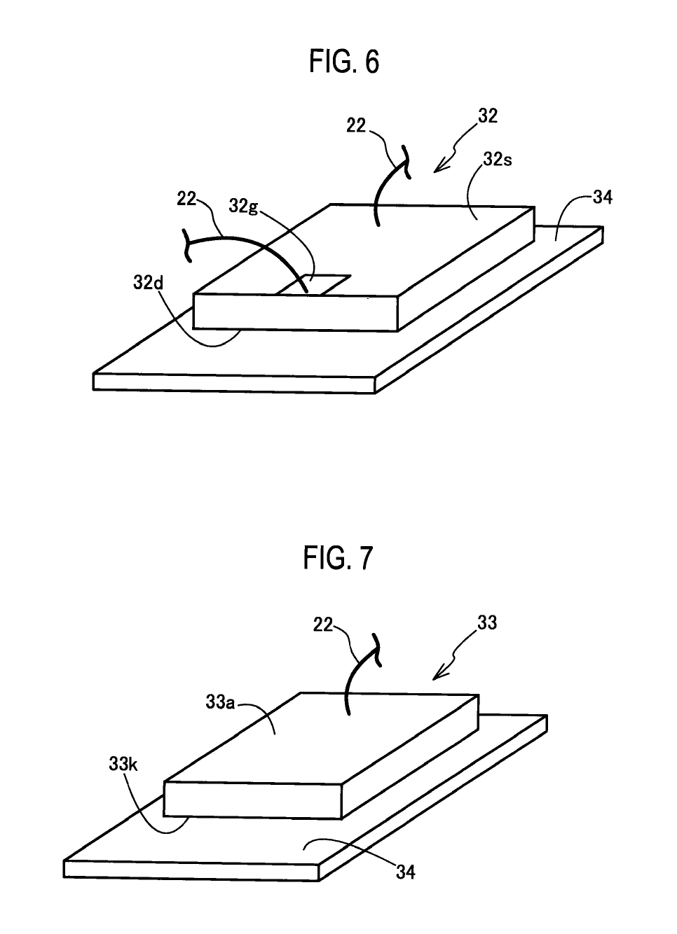

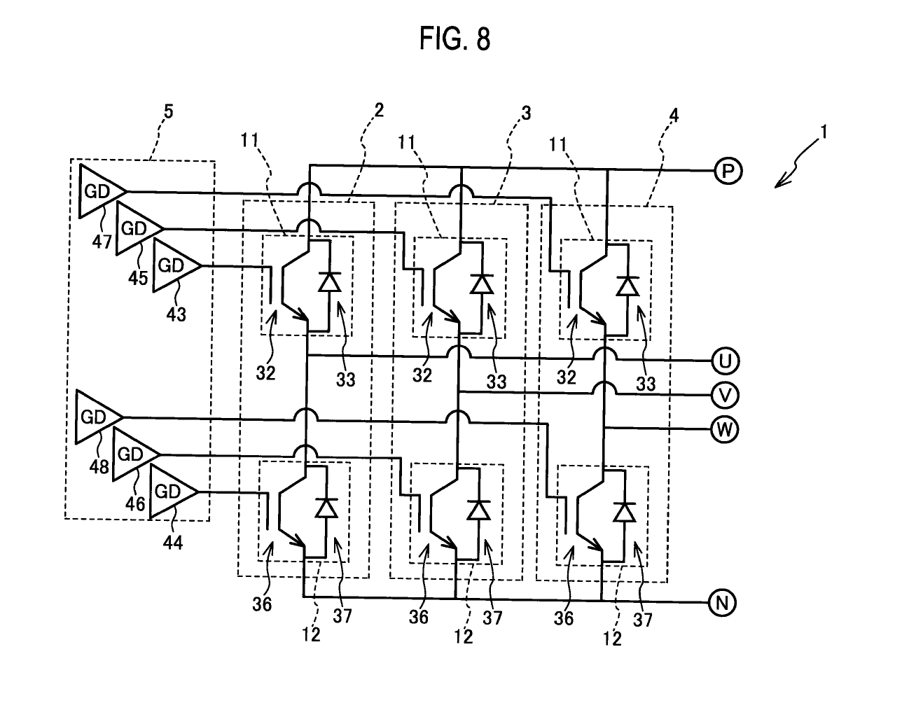

With reference to the drawings, description will be given of a first embodiment in which the present invention is applied to a three-phase intelligent power module (hereinafter referred to as an IPM). FIG. 1 is an overall perspective view of the IPM according to the first embodiment. FIG. 2 is a cross-sectional view along the line II-II in FIG. 1. FIG. 3 is a cross-sectional view along the line III-III in FIG. 1. FIG. 4 is a plan view of a U-phase output unit. FIG. 5 is a cross-sectional view along the line V-V in FIG. 4. FIG. 6 is a perspective view showing a switching device. FIG. 7 is a perspective view showing a diode. FIG. 8 is a schematic circuit diagram of the IPM.

As shown in FIGS. 1 to 3, an IPM 1 according to the first embodiment includes a U-phase output unit 2, a V-phase output unit 3, a W-phase output unit 4, a controller 5, a booster 6 and a cooler 7. The output units 2 to 4 configured to output different phases, the controller 5 and the booster 6 are disposed on different planes of a rectangular parallelepiped, the planes intersecting with each other. Moreover, the output units 2 to 4 and the booster 6 are fixed with screws (not shown) in a state of being provided upright on the controller 5.

As shown in FIGS. 4 and 5, the U-phase output unit 2 includes a high voltage unit 11, a low voltage unit 12, a wiring board 13, a radiator plate 14, seven bus bars 15 to 21, a plurality of Al wires 22 and a case 23.

A direct-current power having a high voltage (positive voltage) is supplied to the high voltage unit 11 from a P side power supply unit. The high voltage unit 11 includes: a switching device 32 formed of an npn-type insulated gate bipolar transistor (IGBT), a metal oxide semiconductor (MOS) transistor or the like; a commutating diode (hereinafter referred to as a diode) 33 for preventing a backflow; and an Al wiring 34 formed on the wiring board 13.

As shown in FIG. 6, a gate 32g and a source 32s are formed on an upper surface of the switching device 32. On a lower surface of the switching device 32, a drain 32d is formed, which is connected to the Al wiring 34 through solder. Note that, in the following description, a drain, a gate and a source of another switching device will also be described by attaching symbols d, g and s to the number of the switching device. As shown in FIGS. 4 and 8, the drain 32d of the switching device 32 is connected to the bus bar 16 for P side power supply through the Al wiring 34 and the Al wire 22. The source 32s of the switching device 32 is connected to the bus bar 15 for U-phase output through the Al wire 22. Moreover, the source 32s of the switching device 32 is also connected to the bus bar 19 for connection to the booster 6 through the Al wire 22. The gate 32g of the switching device 32 is connected to the bus bar 18 for connecting a gate driver through the Al wire 22.

Moreover, a material to form the switching device 32 is not particularly limited, and any of Si, SiC, GaN, AlN, diamond and the like can be used according to applications and purposes. For example, when switching loss or power loss is wished to be suppressed, SiC or GaN is preferable. Note that SiC is also effective in the case of an operation at a high temperature (about 300° C.). Moreover, GaN is preferable when the switching device is wished to be driven at a high frequency. Note that, when GaN is used, unnecessary inductance components (L components) and capacity components (C components) can be suppressed. Thus, miniaturization is also possible. Moreover, when a breakdown voltage is wished to be improved by increasing a breakdown coefficient, AlN is preferable. Note that, when AlN is used and the wiring board 13 is formed of the same AlN, generation of thermal stress attributable to a difference in a thermal expansion coefficient can be suppressed. Moreover, since diamond has a physical value greater than all the materials described above, use of the diamond leads to miniaturization of the IPM 1 and a significant reduction in the power loss or the switching loss.

The diode 33 is for preventing a current from flowing back to the switching device 32. As shown in FIG. 7, an anode 33a is formed on an upper surface of the diode 33. On a lower surface of the diode 33, a cathode 33k is formed, which is connected to the Al wiring 34 through solder. Note that, in the following description, an anode and a cathode of another diode will also be described by attaching symbols a and k to the number of the diode. As shown in FIGS. 4 and 8, the anode 33a of the diode 33 is connected to the bus bar 15 for U-phase output through the Al wire 22. The cathode 33k of the diode 33 is connected to the bus bar 16 for P side power supply through the Al wiring 34 and the Al wire 22. Specifically, the diode 33 is connected so as to allow a current to flow in a forward direction from the source 32s to the drain 32d of the switching device 32. Moreover, a material to form the diode 33 is not particularly limited, and any of Si, SiC, GaN, AlN, diamond and the like can be used according to applications and purposes as in the case of the switching device 32.

A direct-current power having a voltage (negative voltage) which is lower than the power supplied from the P side power supply unit is supplied to the low voltage unit 12 from an N side power supply unit. The low voltage unit 12 includes: a switching device 36 formed of an npn-type IGBT, a MOS (Metal Oxide Semiconductor) transistor or the like; a commutating diode (hereinafter referred to as a diode) 37 for preventing a backflow; and an Al wiring 38 formed on the wiring board 13.

A drain 36d of the switching device 36 is connected to the bus bar 15 for U-phase output through the Al wiring 38 and the Al wire 22. A source 36s of the switching device 36 is connected to the bus bar 17 for N side power supply through the Al wire 22. Moreover, the source 36s of the switching device 36 is also connected to the bus bar 20 for connection to the booster 6 through the Al wire 22. A gate 36g of the switching device 36 is connected to the bus bar 21 for connecting a gate driver.

An anode 37a of the diode 37 is connected to the bus bar 17 for N side power supply through the Al wire 22. A cathode 37k of the diode 37 is connected to the bus bar 15 for U-phase output through the Al wiring 38 and the Al wire 22.

The wiring board 13 is made of insulating Al₂O₃, AlN, Si₃N₄ or SiO₂. On an outer surface of the wiring board 13, the Al wirings 34 and 38 are formed (direct brazed aluminum: DBA). Instead of the Al wirings 34 and 38, a Cu wiring may be formed (direct bonding copper: DBC). Meanwhile, on an inner surface of the wiring board 13, the radiator plate 14 is bonded with a bonding agent (not shown) which is made of metal having good thermal conductivity (for example, Al, Cu or the like).

The radiator plate 14 is for releasing to the outside heat generated by the high voltage unit 11 and the low voltage unit 12, the heat being conducted through the wiring board 13. The radiator plate 14 is insulated from the high voltage unit 11 and the low voltage unit 12 by the insulating wiring board 13. As shown in FIG. 3, the radiator plate 14 is formed of a thermally conductive anisotropic material having a high thermal conductivity in a direction S1 perpendicular to the plane, in other words, the direction S1 different from a direction in which the controller 5 is arranged. As the thermally conductive anisotropic material, for example, one having aligned carbon fibers buried in aluminum or the like is applicable. A peripheral portion of the radiator plate 14 is bonded with an adhesive to an inner surface of the case 23.

The bus bars 15 to 21 are fixed by burying their center portions in the case 23. Thus, one ends of the bus bars 15 to 21 are arranged on a concave portion 23d side of the case 23 and the other ends thereof are arranged outside the case 23. The bus bars 15 to 21 are formed of conductive Cu or Al in the form of plates. The bus bar 15 is for outputting a U-phase. The bus bar 16 is for supplying P-side power. The bus bar 17 is for supplying N-side power. Specifically, a current in a direction opposite to that of a current flowing through the bus bar 17 flows through the bus bar 16. The bus bars 18 and 21 are connected to gate drives 43 and 44 to be described later in the controller 5. Moreover, the bus bars 19 and 20 are connected to the booster 6 through the gate drives 43 and 44.

The case 23 is made of synthetic resin and formed into a rectangular plate. In a center portion of the case 23, a window 23a is formed. The wiring board 13 is fitted into the window 23a. In one side of the case 23, a pair of screw holes 23b having grooves are formed so as to extend to the window 23a. In the other side of the case 23, insertion holes 23c are formed, which penetrate from the outside to the inside of the case. As shown in FIG. 2, screws 26 inserted into the insertion holes 23c of the case 23 are screwed into screw holes 23b of adjacent cases 23. Thus, the cases 23 are fixed to each other. In the case 23, the concave portion 23d slightly larger than the window 23a is formed. The concave portion 23d is filled with protection gel 24 for protecting and insulating the high voltage unit 11, the low voltage unit 12 and the like. The protection gel 24 is made of soft silicon resin or epoxy resin that has a resistance to heat of about 180° C. Moreover, an outer surface of the protection gel 24 is covered with a cover 25 for preventing leak of the protection gel 24 and for suppressing heat conduction to the high voltage unit 11 and the low voltage unit 12.

Since the V-phase output unit 3 and the W-phase output unit 4 have approximately the same configuration as that of the U-phase output unit 2, only differences therebetween will be described. The V-phase output unit 3 outputs a V-phase from the bus bar 15 for output, the V-phase being different in phase from the U-phase. The W-phase output unit 4 outputs a W-phase from the bus bar 15 for output, the W-phase being different in phase from the U-phase and the V-phase. Bus bars 18 and 21 of the V-phase output unit 3 are connected to gate drives 45 and 46 in the controller 5. Moreover, bus bars 19 and 20 of the V-phase output unit 3 are connected to the booster 6 through the gate drives 45 and 46. Bus bars 18 and 21 of the W-phase output unit 4 are connected to gate drives 47 and 48 in the controller 5. Moreover, bus bars 19 and 20 of the W-phase output unit 4 are connected to the booster 6 through the gate drives 47 and 48.

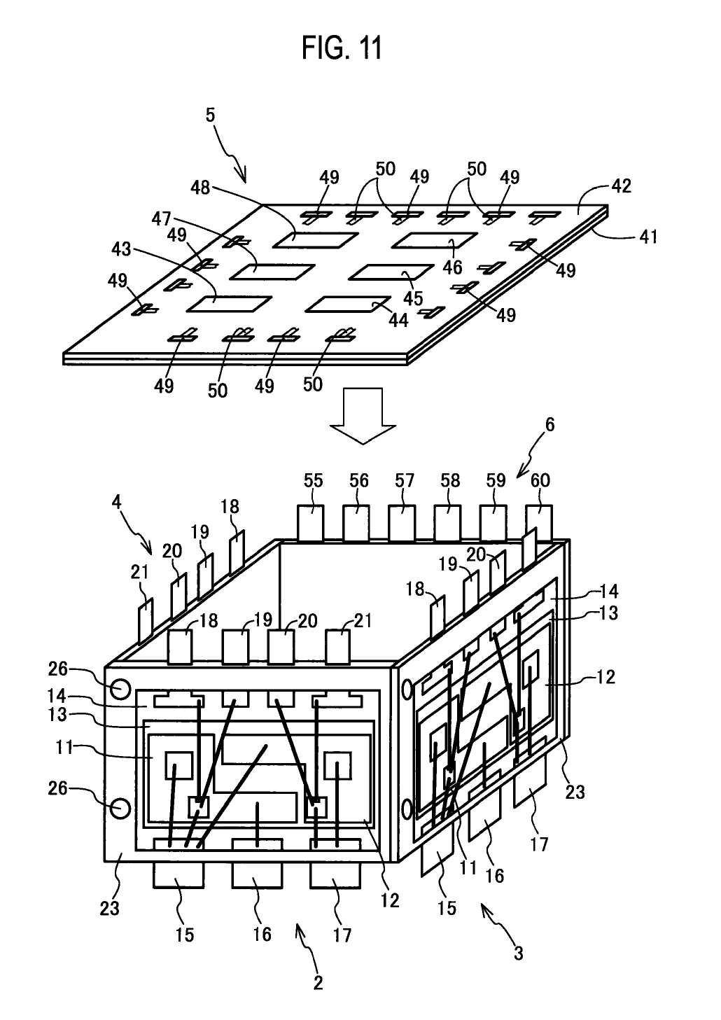

The controller 5 includes a heat insulator 41, a wiring board 42, the six gate drives 43 to 48 and Al wirings 50. Note that only some of the Al wirings 50 are illustrated in the drawings. The heat insulator 41 is for suppressing conduction of heat from the phase output units 2 to 4 to the heat sensitive gate drives 43 to 48, respectively. The heat insulator 41 is made of insulating polyimide resin that has a resistance to heat of about 350° C., and is disposed between the wiring board 42 and the respective phase output units 2 to 4. In peripheral portions of the heat insulator 41 and the wiring board 42, holes 49 (see FIG. 11) for inserting therethrough the bus bars 15 to 21 for control and bus bars 55 to 60 are formed. The Al wirings 50 for respectively connecting the bus bars 18 to 21, the gate drives 43 to 48 and the bus bars 55 to 60 are extended from the respective holes 49. The bus bars 18 to 21 and the bus bars 55 to 60 are connected to the Al wirings 50 by use of solder.

The respective gate drives 43 to 48 are provided on the wiring board 42. The gate drive 43 (44) is for controlling the gate 32g (36g) of the switching device 32 (36) provided in the U-phase output unit 2. The gate drive 45 (46) is for controlling the gate 32g (36g) of the switching device 32 (36) provided in the V-phase output unit 3. The gate drive 47 (48) is for controlling the gate 32g (36g) of the switching device 32 (36) provided in the W-phase output unit 4.

As shown in FIG. 2, the booster 6 includes a booster circuit unit 51, an Al wiring 52, a wiring board 53, a radiator plate 54, the six bus bars 55 to 60 connected to the gate drives 43 to 48, and the case 23. The booster 6 controls voltages of the sources 32s and 36s of the switching devices 32 and 36 in the respective output units 2 to 4 connected through the gate drives 43 to 48, the bus bars 19 and 20 and the bus bars 55 to 60. Thus, voltages of the gates 32g and 36g of the switching devices 32 and 36 are stabilized to suppress application of a high voltage to the gates 32g and 36g.

The cooler 7 includes a tube member 61 and a cooling fan 62. The tube member 61 is attached to the case 23 by use of a fixing member (not shown). There is a predetermined space between one end of the tube member 61 and the controller 5. At the other end of the tube member 61, the cooling fan 62 is provided. The cooling fan 62 is configured so as to be able to send air toward the controller 5.

Next, operations of the IPM 1 will be described.

When the power is supplied from the bus bar 16 for P-side power supply and the bus bar 17 for N-side power supply while controlling the gates 32g and 36g of the switching devices 32 and 36 by the gate drives 43 to 48, three-phase alternating-current power having different phases is outputted by the phase output units 2 to 4. Moreover, during the operation, air sent from the cooling fan 62 flows in a direction F1 indicated by the arrows shown in FIG. 3. Thus, the sent air passes through the tube member 61 and reaches the controller 5. The air cools the controller 5 and then flows in directions F2 indicated by the arrows outside the tube member 61. Thereafter, the air cools the phase output units 2 to 4 and the booster 6 and then is discharged.

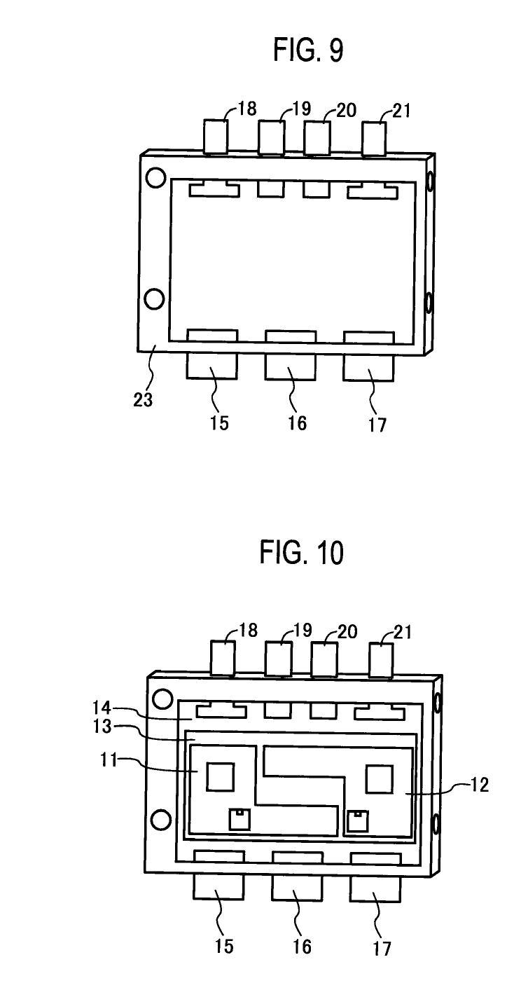

Next, steps of assembling the IPM 1 will be described. FIGS. 9 to 11 are perspective views showing the steps of assembling the IPM.

First, as shown in FIG. 9, the case 23 is prepared by injection molding in a state where the bus bars 15 to 21 are placed in a mold. Next, as shown in FIG. 10, the radiator plate 14, on which the high voltage unit 11, the low voltage unit 12 and the wiring board 13 are bonded, is bonded to the case 23. Thereafter, as shown in FIG. 4, the Al wires 22 are laid out. Next, as shown in FIG. 11, the cases 23 of the output units 2 to 4 and the booster 6 are fixed to each other with the screws 26. Thereafter, the controller 5 is placed on the output units 2 to 4 and the booster 6 and fixed thereto with screws (not shown) so as to allow the bus bars 15 to 21 and the bus bars 55 to 60 to correspond to the holes 49 in the controller 5. Thus, the bus bars 15 to 21 and the bus bars 55 to 60 are electrically connected with solder to the Al wirings 50. Subsequently, the cooler 7 is attached to complete the IPM 1.

As described above, in the IPM 1 according to the first embodiment, the output units 2 to 4, the controller 5 and the booster 6 are disposed on the different planes of the rectangular parallelepiped, the planes intersecting with each other. Thus, compared with the case where all the above components are disposed on the same plane, a plane area can be reduced. Moreover, since the IPM is formed into a polyhedron, an increase in the plane area can be suppressed even when a rectifier circuit and the like are newly provided. Furthermore, since the IPM is formed into the polyhedron, the switching devices 32 and 36 and the diodes 33 and 37 can be prevented from being adjacent to each other. Thus, concentration of heat can be suppressed.

Moreover, in the IPM 1, the output units 2 to 4, the controller 5 and the booster 6 are disposed on the different planes of the rectangular parallelepiped, the planes intersecting with each other. Thus, the air for cooling can be easily sent and the cooling can be performed by mounting one cooler 7 inside the rectangular parallelepiped. Accordingly, a cooling function can be improved. Thus, even if the output units 2 to 4 are operated at a high temperature (for example, about 200° C.), breakage of the gate drives 43 to 48 sensitive to heat can be suppressed. As a result, life of the IPM 1 can be extended.

Moreover, generally, in most cases, the gate drives are formed on the output units. Thus, heat from the output units are easily transmitted to the gate drives. However, in the IPM 1, the output units 2 to 4 are provided at right angles to the controller 5. Thus, heat transmission from the output units 2 to 4 to the controller 5 can be suppressed. Furthermore, heat transmission can be further suppressed by providing the heat insulator 41 between the gate drives 43 to 48 and the output units 2 to 4.

Moreover, the bus bars 15 to 21 for control and the bus bars 55 to 60 are connected to the Al wirings 50 in a state where the bus bars are inserted into the holes 49 in the controller 5. Thus, positioning and connection can be easily performed.

### Second Embodiment

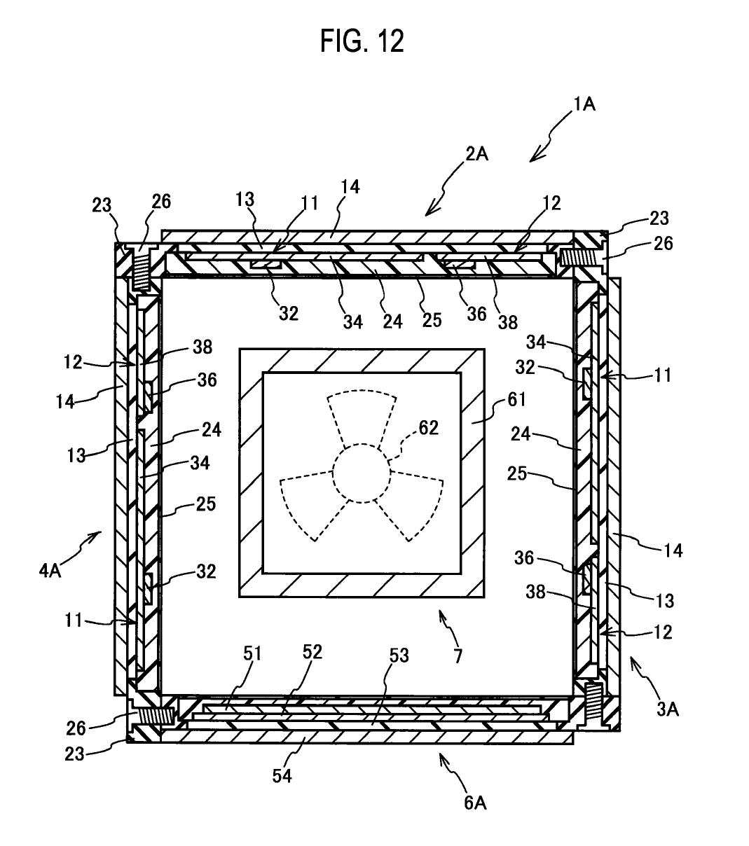

Next, description will be given of a second embodiment obtained by partially modifying the first embodiment described above. Note that the same constituent components as those of the first embodiment are denoted by the same reference numerals and description thereof will be omitted. FIG. 12 is a cross-sectional view equivalent to FIG. 2, showing an IPM according to the second embodiment.

As shown in FIG. 12, in each of a U-phase output unit 2A, a V-phase output unit 3A and a W-phase output unit 4A in an IPM 1A according to the second embodiment, a radiator plate 14 is disposed on the outside of a wiring board 13, and a high voltage unit 11 and a low voltage unit 12 are disposed on the inside of the wiring board 13. Moreover, also in a booster 6A, a radiator plate 54 is disposed on the outside of a wiring board 53, and a booster circuit unit 51 is disposed on the inside of the wiring board 53.

In the IPM 1A of the second embodiment, heat radiation properties can be further improved by disposing the radiator plates 14 and 54 on the outside of the rectangular parallelepiped. Note that, when the IPM is thus configured, heat sinks, fins or the like may be provided in the radiator plates 14 and 54.

### Third Embodiment

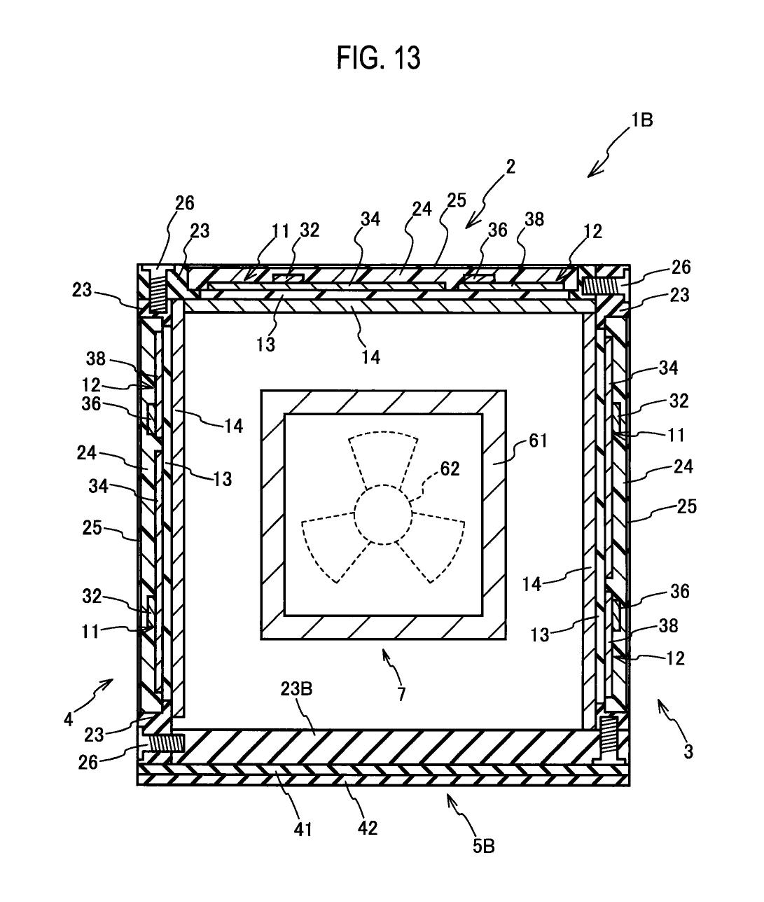

Next, description will be given of a third embodiment obtained by partially modifying the first embodiment described above. Note that the same constituent components as those of the first embodiment are denoted by the same reference numerals and description thereof will be omitted. FIG. 13 is a cross-sectional view equivalent to FIG. 2, showing an IPM according to the third embodiment.

As in an IPM 1B shown in FIG. 13, a booster may be omitted and a controller 5B may be provided at a position of the booster. Specifically, a case 23B is attached to the position where the booster has been disposed, and a heat insulator 41 and a wiring board 42 having gate drives (not shown) provided therein are sequentially stacked on the outside of the case 23B.

In the IPM 1B according to the third embodiment, phase output units 2 to 4 and a controller 5A are disposed on respectively different sides of the rectangular parallelepiped. Thus, air permeability is improved. Consequently, cooling performance can be further improved.

### Fourth Embodiment

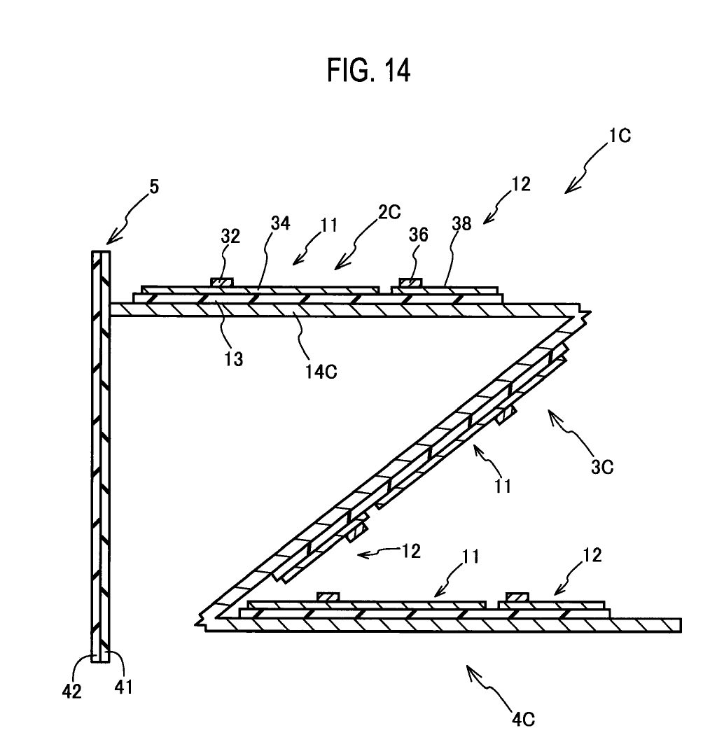

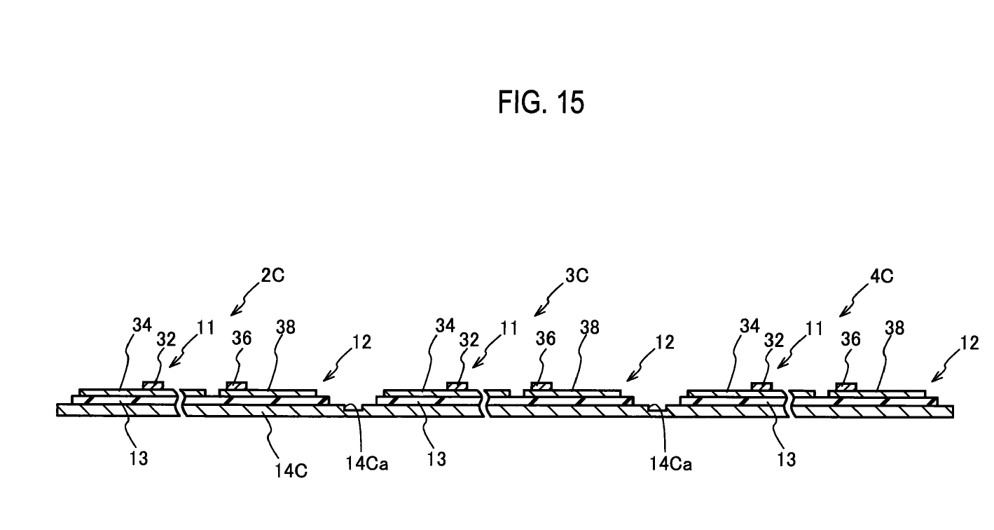

Next, description will be given of a fourth embodiment obtained by partially modifying the first embodiment described above. Note that the same constituent components as those of the first embodiment are denoted by the same reference numerals and description thereof will be omitted. FIG. 14 is a cross-sectional view of an IPM according to the fourth embodiment. FIG. 15 is a view before a step of bending the IPM according to the fourth embodiment.

As shown in FIG. 14, in an IPM 1C according to the fourth embodiment, a U-phase output unit 2C, a V-phase output unit 3C and a W-phase output unit 4C are disposed on different planes of one radiator plate 14C bent into a Z shape. Moreover, on one end face of the U-phase output unit 2C, a controller 5 is disposed.

In the case of assembly of the IPM 1C according to the fourth embodiment, as shown in FIG. 15, concave portions 14Ca extended vertically in FIG. 15 are formed in the radiator plate 14C so as to partially reduce the thicknesses of the radiator plate 14C between the output units 2C and 3C and between the output units 3C and 4C. Note that, as an example of the thickness, it is conceivable that a thickness of each of the concave portions 14Ca is set to about 1 mm to 1.5 mm when a thickness of a thick portion of the radiator plate 14C is about 3 mm. After the respective output units 2C to 4C are placed on the radiator plate 14C, the radiator plate 14C is bent along the concave portions 14Ca of the radiator plate 14C. Thus, the radiator plate 14C is formed into the Z shape.

As described above, by disposing the output units 2C to 4C in a Z-shaped pattern, not only a plane area but also a thickness (a distance between the U-phase output unit 2C and the W-phase output unit 4C) can be reduced. Moreover, by disposing the output units 2C to 4C on one radiator plate 14C, the number of components can be reduced. Furthermore, by providing a space between the W-phase output unit 4C and the controller 5, air permeability is improved. Thus, cooling performance can be improved.

### Fifth Embodiment

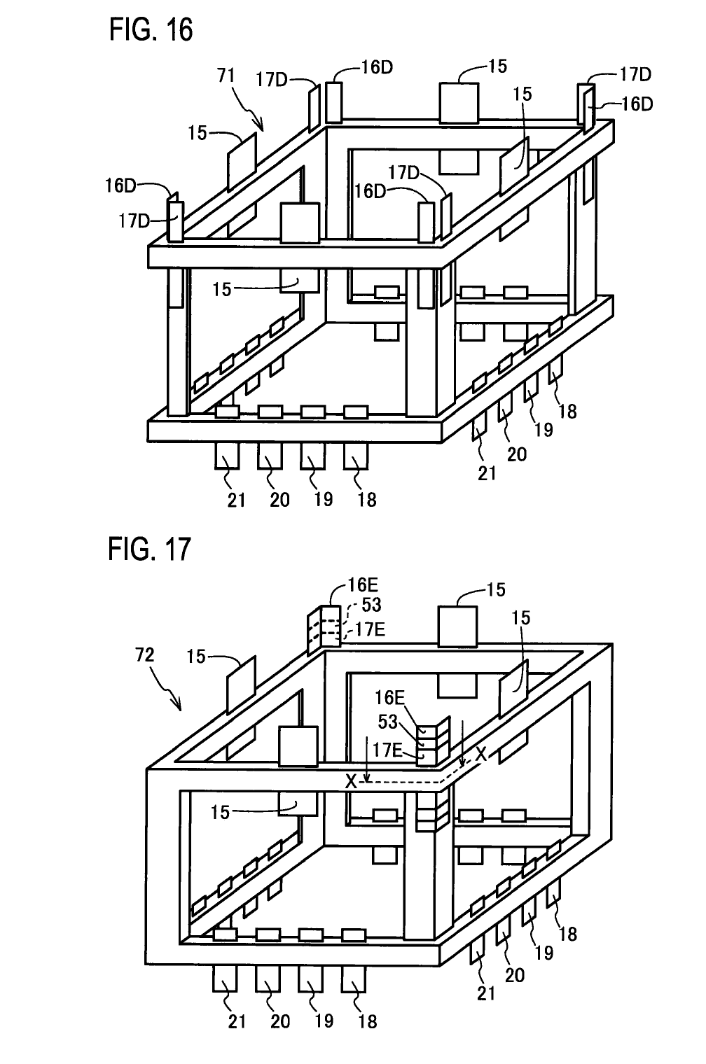

Next, description will be given of a fifth embodiment obtained by modifying the case and the bus bars in the first embodiment described above. Note that the same constituent components as those of the first embodiment are denoted by the same reference numerals and description thereof will be omitted. FIG. 16 is a perspective view showing a case and bus bars according to the fifth embodiment.

In the fifth embodiment, two bus bars for power supply in adjacent phases are integrated, the two bus bars being separately formed in the first embodiment. To be more specific, as shown in FIG. 16, a case 71 is integrally formed into a rectangular parallelepiped shape, and bus bars 16D for P-side power supply and bus bars 17D for N-side power supply are disposed adjacent to each other near corners of the case 71. Specifically, for example, the bus bar 16D of the U-phase output unit 2 is disposed at a position closer to the bus bar 17D of the V-phase output unit 3, through which a current flows in an opposite direction, than the bus bar 16D of the V-phase output unit 3, through which a current flows in the same direction. Note that a bus bar 15 for output is disposed in the middle of each side.

As described above, the bus bars 16D and 17D having opposite current directions are disposed adjacent to each other in the adjacent output units 4 to 6. Thus, parasitic inductances generated in the bus bars 16D and 17D can be cancelled.

### Sixth Embodiment

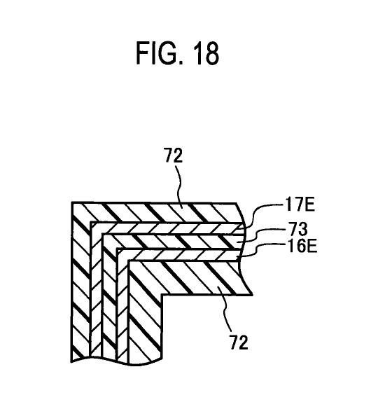

Next, description will be given of a sixth embodiment obtained by modifying the case and the bus bars in the first embodiment described above. Note that the same constituent components as those of the first embodiment are denoted by the same reference numerals and description thereof will be omitted. FIG. 17 is a perspective view showing a case and bus bars according to the sixth embodiment. FIG. 18 is a cross-sectional view along the line X-X in FIG. 17.

In the sixth embodiment, two bus bars for power supply are disposed at the same position, the two bus bars being disposed at different corners in the fifth embodiment. To be more specific, as shown in FIGS. 17 and 18, bus bars 16E for P-side power supply, insulating layers 73 and bus bars 17E for N-side power supply, through which currents flow in a direction opposite to that of currents flowing through the bus bars 16E, are stacked on two corners of a case 72. Moreover, adjacent output units 2 to 4 share the bus bars 16E and 17E. Note that the lower bus bars 16E are formed so as to be longer than the upper bus bars 17E.

According to the configuration described above, parasitic inductances generated in the bus bars 16E and 17E can be further cancelled. Moreover, by sharing the bus bars 16E and 17E, the number of the bus bars 16E and 17E can be reduced. Thus, the number of components can be reduced. Consequently, the parasitic inductances can be reduced.

### Seventh Embodiment

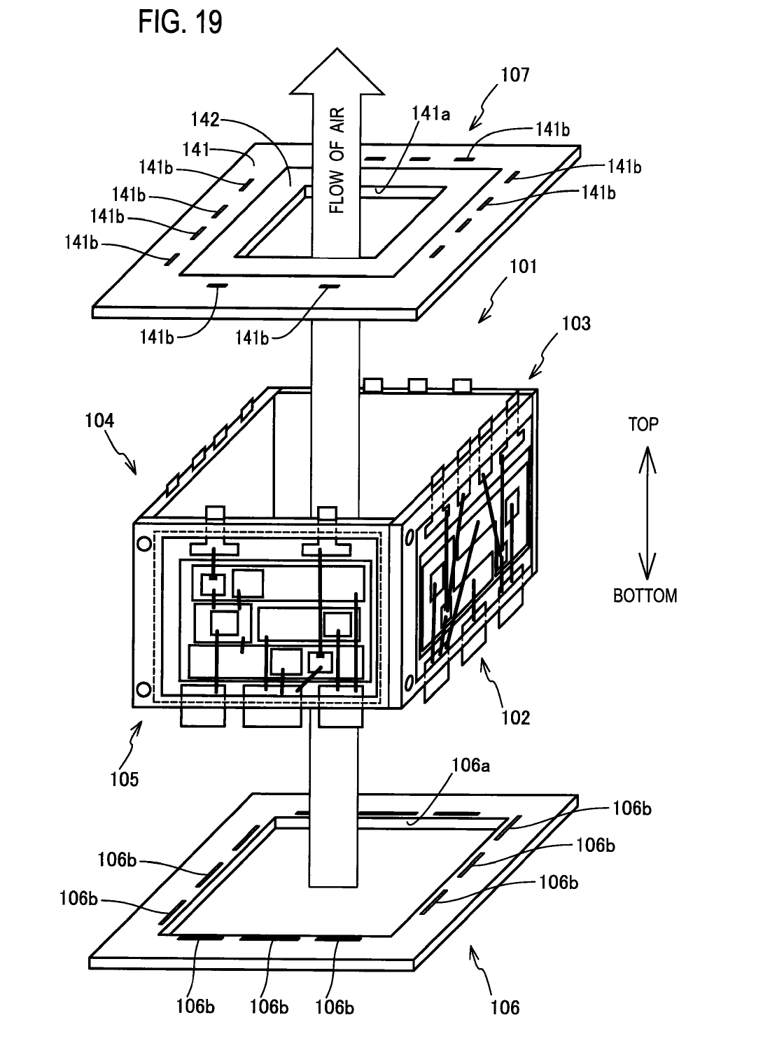

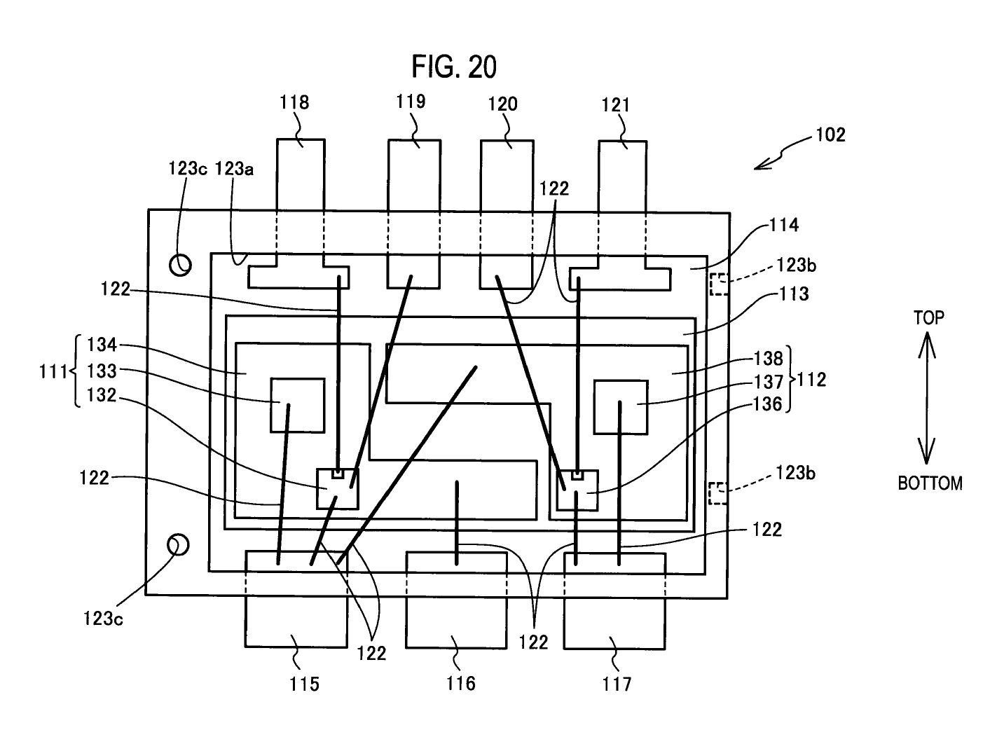

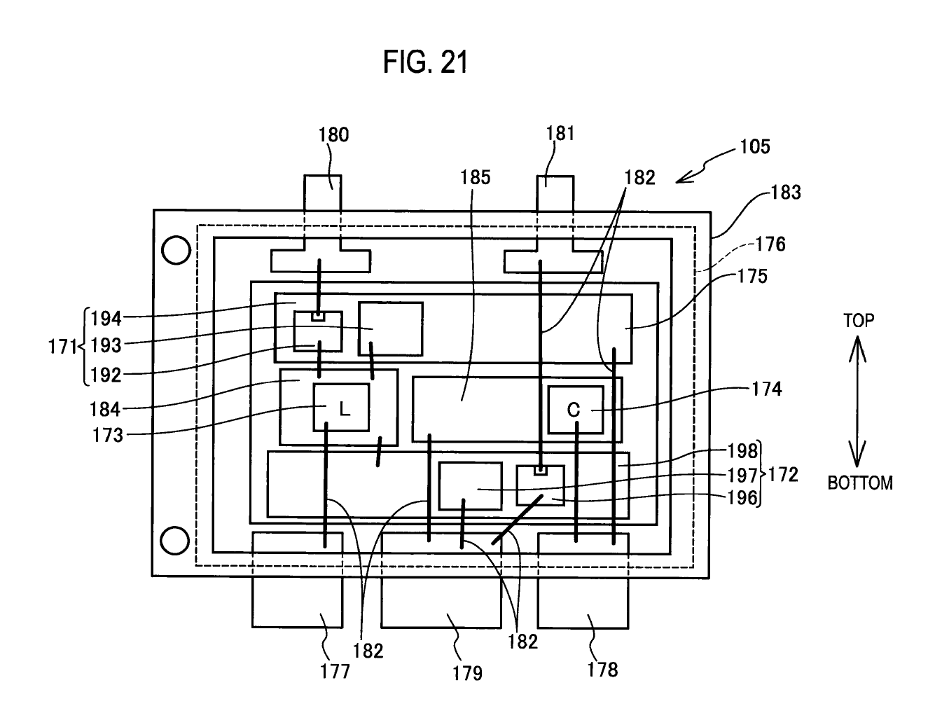

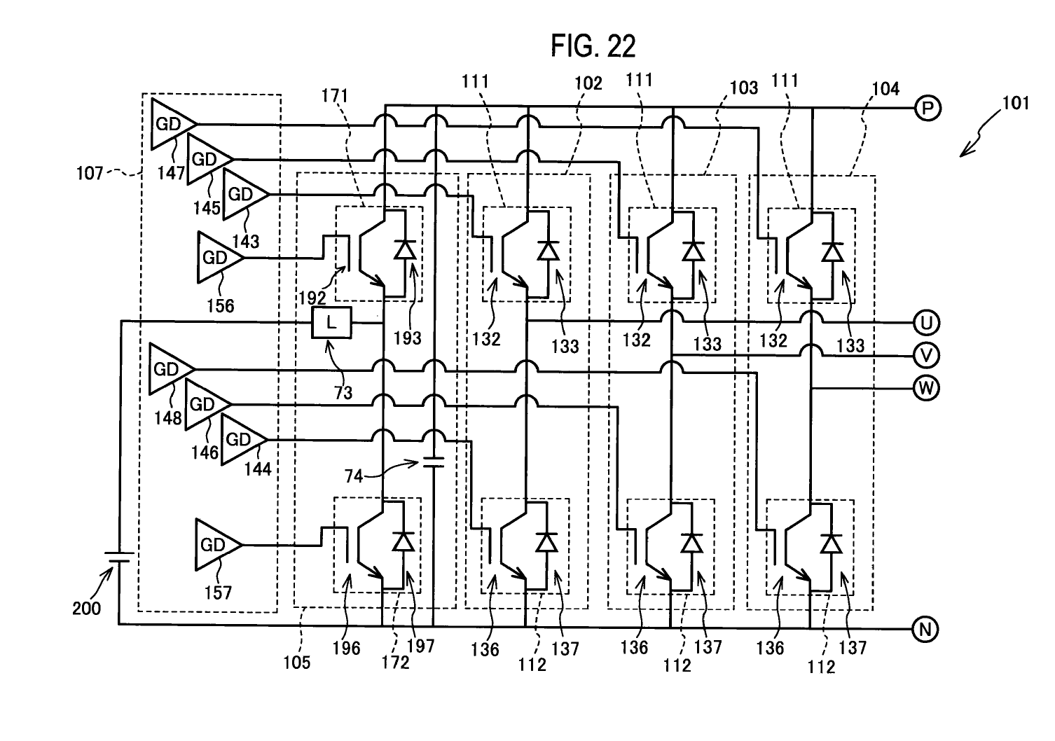

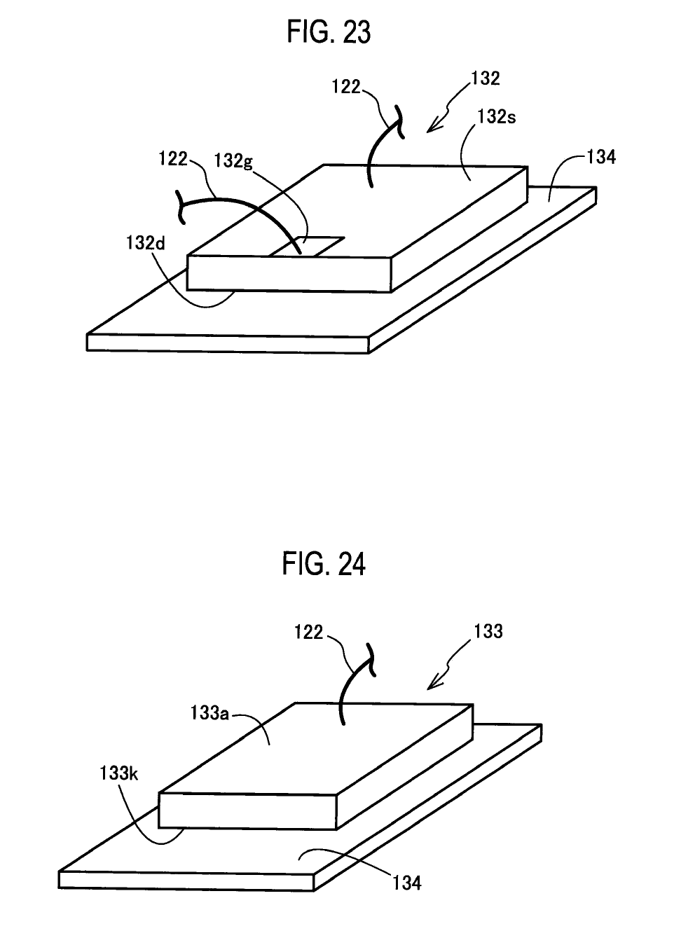

Next, with reference to the drawings, description will be given of a seventh embodiment in which the semiconductor device of the present invention is applied to a power module. FIG. 19 is an overall perspective view of the power module according to the seventh embodiment. FIG. 20 is a plan view of a U-phase output unit. FIG. 21 is a plan view of a booster. FIG. 22 is a circuit diagram of the power module. FIG. 23 is a perspective view of a switching device. FIG. 24 is a perspective view of a diode.

As shown in FIGS. 19 to 22, a power module 101 according to the seventh embodiment includes a U-phase output unit 102, a V-phase output unit 103, a W-phase output unit 104 and a booster (equivalent to a voltage regulator in the claims) 105. The output units 102 to 104 and the booster 105 are disposed on the respective sides of a rectangular parallelepiped, the sides being different planes intersecting with each other, to form a hollow structure. The power module 101 is installed on an installation substrate 106. Moreover, on one surface of the power module 101, a controller 107 having gate drives 144 to 148, 156 and 157 provided therein is disposed.

As shown in FIG. 20, the U-phase output unit 102 includes a high voltage unit 111, a low voltage unit 112, a substrate 113, a radiator plate 114, seven bus bars 115 to 121, a plurality of Al wires 122 and a case 123.

A high-voltage power is supplied to the high voltage unit 111 from the booster 105. The high voltage unit 111 includes: a switching device 132 formed of an npn-type IGBT (Insulated Gate Bipolar Transistor), a MOS (Metal Oxide Semiconductor) transistor or the like; a commutating diode (hereinafter referred to as a diode) 133 for preventing a backflow; and an Al wiring 134 formed on the substrate 113.

As shown in FIG. 23, a gate 132g and a source 132s are formed on an upper surface of the switching device 132. On a lower surface of the switching device 132, a drain 132d is formed, which is connected to the Al wiring 134 through solder. Note that, in the following description, a drain, a gate and a source of another switching device will also be described by attaching symbols d, g and s to the number of the switching device. As shown in FIG. 20, the drain 132d of the switching device 132 is connected to the bus bar 116 for P-side power supply through the Al wiring 134 and the Al wire 122. The source 132s of the switching device 132 is connected to the bus bar 115 for U-phase output through the Al wire 122. Moreover, the source 132s of the switching device 132 is also connected to the bus bar 119 for connection to the booster 105 through the Al wire 122. The gate 132g of the switching device 132 is connected to the bus bar 118 for connecting a gate driver through the Al wire 122.

Moreover, a material to form the switching device 132 is not particularly limited, and any of Si, SiC, GaN, AlN, diamond and the like can be used according to applications and purposes. For example, when switching loss or power loss is wished to be suppressed, SiC or GaN is preferable. Note that SiC is also effective in the case of an operation at a high temperature (about 300° C.). Moreover, GaN is preferable when the switching device is wished to be driven at a high frequency. Note that, when GaN is used, unnecessary inductance components (L components) and capacity components (C components) can be suppressed. Thus, miniaturization is also possible. Moreover, when a breakdown voltage is wished to be improved by increasing a breakdown coefficient, AlN is preferable. Note that, when AlN is used to form both the switching device 132 and the substrate 113, generation of thermal stress attributable to a difference in a thermal expansion coefficient can be suppressed. Moreover, since diamond has a physical value greater than all the materials described above, use of the diamond leads to miniaturization of the power module 101 and a significant reduction in the power loss or the switching loss.

The diode 133 is for preventing a current from flowing back to the switching device 132. As shown in FIG. 24, on an upper surface of the diode 133, an anode 133a is formed. On a lower surface of the diode 133, a cathode 133k is formed, which is connected to the Al wiring 134 through solder. Note that, in the following description, an anode and a cathode of another diode will also be described by attaching symbols a and k to the number of the diode. As shown in FIG. 20, the anode 133a of the diode 133 is connected to the bus bar 115 for U-phase output through the Al wire 122. The cathode 133k of the diode 133 is connected to the bus bar 116 for P side power supply through the Al wiring 134 and the Al wire 122. Specifically, the diode 133 is connected so as to allow a current to flow in a forward direction from the source 32s to the drain 32d of the switching device 132. Moreover, a material to form the diode 133 is not particularly limited, and any of Si, SiC, GaN, AlN, diamond and the like can be used according to applications and purposes as in the case of the switching device 132.

A power having a voltage (negative voltage) which is lower than the power supplied to the high voltage unit 111 is supplied to the low voltage unit 112 from the booster 105. As shown in FIG. 20, the low voltage unit 112 includes: a switching device 136 formed of an npn-type IGBT, a MOS transistor or the like; a commutating diode (hereinafter referred to as a diode) 137 for preventing a backflow; and an Al wiring 138 formed on the substrate 113.

A drain 136d of the switching device 136 is connected to the bus bar 115 for U-phase output through the Al wiring 138 and the Al wire 122. A source 136s of the switching device 136 is connected to the bus bar 117 for N side power supply through the Al wire 122. Moreover, the source 136s of the switching device 136 is also connected to the bus bar 120 for connection to the booster 105 through the Al wire 122. A gate 136g of the switching device 136 is connected to the bus bar 121 for connecting a gate driver.

An anode 137a of the diode 137 is connected to the bus bar 117 for N side power supply through the Al wire 122. A cathode 137k of the diode 137 is connected to the bus bar 115 for U-phase output through the Al wiring 138 and the Al wire 122.

The substrate 113 is made of insulating Al₂O₃, AlN, Si₃N₄ or SiO₂. On an outer surface of the substrate 113, the Al wirings 134 and 138 are formed (DBA (Direct Brazed Aluminum)). Instead of the Al wirings 134 and 138, a Cu wiring may be formed (DBC (Direct Bonding Copper)). Meanwhile, on an inner surface of the substrate 113, the radiator plate 114 is bonded with a bonding agent (not shown) which is made of metal having good thermal conductivity (for example, Al, Cu or the like).

The radiator plate 114 is for releasing to the outside heat generated by the high voltage unit 111 and the low voltage unit 112, the heat being conducted through the substrate 113. The radiator plate 114 is insulated from the high voltage unit 11 and the low voltage unit 12 by the insulating substrate 113. The radiator plate 114 is formed of a thermally conductive anisotropic material having a high thermal conductivity in a direction perpendicular to the plane, in other words, the direction different from a direction in which the controller 107 is arranged. As the thermally conductive anisotropic material, for example, one having aligned carbon fibers buried in aluminum or the like is applicable. A peripheral portion of the radiator plate 114 is bonded with an adhesive to an inner surface of the case 123.

The bus bars 115 to 121 are fixed by burying their center portions in the case 123. Thus, one ends of the bus bars 115 to 121 are arranged on a concave portion 123d side of the case 123 and the other ends thereof are arranged outside the case 123. The bus bars 115 to 121 are formed of conductive Cu or Al in the form of plates. The bus bar 115 is for outputting a U-phase. The bus bar 116 is for supplying P-side power. The bus bar 117 is for supplying N-side power. Specifically, a current in a direction opposite to that of a current flowing through the bus bar 117 flows through the bus bar 116. The bus bars 118 and 121 are connected to gate drives 143 and 144 to be described later in the controller 107. Moreover, the bus bars 119 and 120 are connected to the booster 105 through the gate drives 143 and 144.

The case 123 is made of synthetic resin and formed into a rectangular plate. In a center portion of the case 123, a window 123a is formed. The substrate 113 is fitted into the window 123a. In one side of the case 123, a pair of screw holes 123b having grooves are formed so as to extend to the window 123a. In the other side of the case 123, insertion holes 123c are formed, which penetrate from the outside to the inside of the case. By screwing screws (not shown) into screw holes 123b of adjacent cases 123, the screws being inserted into the insertion holes 123c of the case 123, the cases 123 are fixed to each other.

Since the V-phase output unit 103 and the W-phase output unit 104 have approximately the same configuration as that of the U-phase output unit 102, only differences therebetween will be described. The V-phase output unit 103 outputs a V-phase from the bus bar 115 for output, the V-phase being different in phase from the U-phase. The W-phase output unit 104 outputs a W-phase from the bus bar 115 for output, the W-phase being different in phase from the U-phase and the V-phase. Bus bars 118 and 121 of the V-phase output unit 103 are connected to gate drives 145 and 146 in the controller 107. Moreover, bus bars 119 and 120 of the V-phase output unit 103 are connected to the booster 105 through the gate drives 145 and 146. Bus bars 118 and 121 of the W-phase output unit 104 are connected to gate drives 147 and 148 in the controller 107. Moreover, bus bars 119 and 120 of the W-phase output unit 104 are connected to the booster 105 through the gate drives 147 and 148.

As shown in FIG. 21, the booster 105 includes a high voltage unit 171, a low voltage unit 172, a coil 173, a capacitor 174, a substrate 175, a radiator plate 176, five plate-like bus bars 177 to 181 made of Cu or Al, a plurality of Al wires 182, a case 183 and Al wirings 184 and 185.

As shown in FIGS. 21 and 22, the high voltage unit 171 includes: a switching device 192 formed of a transistor that can be switched on and off; a diode 193 for preventing a backflow; and an Al wiring 194. A source 192s of the switching device 192 is connected to the coil 173 through the Al wiring 184. A drain 192d of the switching device 192 is connected to the bus bar 178 for P-side power supply, to which one end of the capacitor 174 is connected, through the Al wiring 194. A gate 192g of the switching device 192 is connected to the gate drive 156 in the controller 107 through the bus bar 180. An anode 193a of the diode 193 is connected to one end of the coil 173 and the source 192s of the switching device 192 through the Al wiring 184. A cathode 193k of the diode 193 is connected to the bus bar 178, to which the one end of the capacitor 174 is connected, through the Al wiring 194.

The low voltage unit 172 includes: a switching device 196 formed of a transistor that can be switched on and off; a diode 197 for preventing a backflow; and an Al wiring 198. Note that a voltage lower than the voltage applied to the high voltage unit 171 is applied to the low voltage unit 172 by an external power source 200. A source 196s of the switching device 196 is connected to the bus bar 179 for N-side power supply, which is connected to a negative electrode of the power source 200 and one end of the capacitor 174. A drain 196d of the switching device 196 is connected to one end of the coil 173 through the Al wiring 198. A gate 196g of the switching device 196 is connected to the gate drive 157 in the controller 107 through the bus bar 181. An anode 197a of the diode 197 is connected to the bus bar 179 for N-side power supply. A cathode 197k of the diode 197 is connected to the one end of the coil 173 through the Al wiring 198.

The one end of the coil 173 is connected to the source 192s of the switching device 192, the anode 193a of the diode 193, the drain 196d of the switching device 196 and the cathode 197k of the diode 197 through the Al wiring 184. The other end of the coil 173 is connected to a positive electrode of the power source 200 through the bus bar 177.

The one end of the capacitor 174 is connected to the bus bar 178 for supplying P-side power to the output units 102 to 104. The other end of the capacitor 174 is connected to the bus bar 179 for supplying N-side power to the output units 102 to 104 through the Al wiring 185.

The substrate 175 has the same configuration as that of the substrate 113 of each of the output units 102 to 104. The radiator plate 176 has the same configuration as that of the radiator plate 114 of each of the output units 102 to 104. The case 183 has the same configuration as that of the case 123 of each of the output units 102 to 104.

Next, the installation substrate 106 and the controller 107 will be briefly described.

The installation substrate 106 is for installing the power module 101. In a center portion of the installation substrate 106, a quadrangle hole 106a is formed. In a peripheral portion of the hole 106a, insertion holes 106b are formed, into which the bus bars 118 to 121, 180 and 181 are inserted. The power module 101 is installed on the installation substrate 106 so as to allow the hole 106a to approximately coincide with the hollow portion of the power module 101.

The controller 107 is for controlling the gates of the switching devices 192 to 196 provided in the output units 102 to 104 and the booster 105. The controller 107 includes a wiring board 141 and a gate drive unit 142 having the plurality of gate drives (see FIG. 22) 143 to 148, 156 and 157 provided therein. In a center portion of the wiring board 141, a hole 141a for allowing a convection current from the power module 101 to flow upward is formed. In a peripheral portion of the hole 141a, a plurality of insertion holes 141b are formed, into which the bus bars 115 to 117 and 177 to 179 are inserted.

Next, operations of the power module 101 will be described.

First, a voltage of 200 V is applied to the booster 105 in the power module 101 from the power source 200. Here, when the switching device 196 in the low voltage unit 172 is on, currents flow through the coil 173 and the switching device 196. When the switching device 196 in the low voltage unit 172 is switched off from the above state, the flowing current is blocked and electromotive force is generated in the coil 173. When the switching device 192 in the high voltage unit 171 is switched off in the state where the electromotive force is generated in the coil 173, charges are supplied to the capacitor 174 from the coil 173 through the high voltage unit 171. Thus, the charges are accumulated in the capacitor 174 by the voltage of the power source 200 and the electromotive force in the coil 173. As a result, the voltage of the power source 200 is increased by the capacitor 174 and then applied to the respective output units 102 to 104.

Here, frequencies for switching on and off the switching devices 192 and 196 in the booster 105 are higher than those for switching on and off the switching devices 132 and 136 in the respective output units 102 to 104. Furthermore, a frequency for switching on and off the switching device 196 of the low voltage unit 172 in the booster 105 is higher than that for switching on and off the switching device 192 of the high voltage unit 171 in the booster 105. Therefore, a temperature of the booster 105 is higher than that of each of the output units 102 to 104. Furthermore, in the booster 105, a temperature of the low voltage unit 172 is higher than that of the high voltage unit 171.

As described above, when the power is supplied from the bus bar 116 for P-side power supply and the bus bar 117 for N-side power supply while the gates 132g and 136g of the switching devices 132 and 136 are controlled by the gate drives 143 to 148 in the state where the voltage increased to 600 V by the booster 105 is applied to the output units 102 to 104, three-phase alternating-current power having different phases is outputted by the phase output units 102 to 104.

As described above, the power module 101 according to the seventh embodiment includes the booster 105 in which the low voltage unit 172 is disposed below the high voltage unit 171, that is, upstream of the high voltage unit 171 in the air flow. Here, the frequency of the switching device 196 in the low voltage unit 172 is higher than that of the switching device 192 in the high voltage unit 171. Thus, during the operation of the power module 101, the temperature of the low voltage unit 172 becomes higher than that of the high voltage unit 171. By disposing the low voltage unit 172, of which temperature rises, below the high voltage unit 171 as described above, the air flows from the low voltage unit 172 to the high voltage unit 171. Therefore, compared with the case where the low voltage unit is disposed above the high voltage unit, temperature rise of the switching device 196 in the low voltage unit 172 can be suppressed. As a result, deterioration of the switching device 196 can be suppressed. Thus, reliability can be improved.

Moreover, since the temperature rise in the booster 105 can be suppressed, outputs from the booster 105 can be increased. Therefore, even though the conventional booster undergoing significant temperature rise requires a plurality of boosters to be provided for their respective output units, the power module 101 requires only one booster 105 to be provided for all the output units 102 to 104. As a result, the power module 101 can be miniaturized. Furthermore, by providing only one booster 105, the controller 107 can also be miniaturized.

### (Experiment)

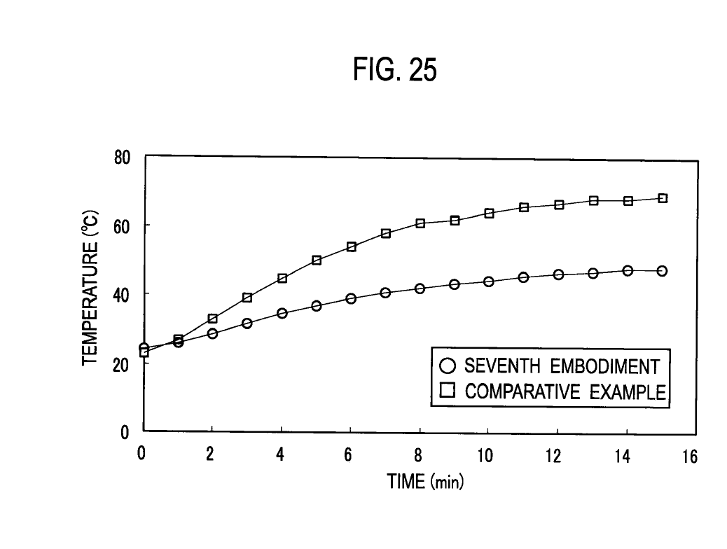

Next, description will be given of an experiment conducted to prove the effects of the seventh embodiment described above. In this experiment, a drain voltage Vd=5.18 [V] and a gate voltage Vg=10.64 [V] are applied to the power module according to the seventh embodiment. In this event, a drain current is Id=12.50 [A] and a heating value of the power module is 62.75 [W]. This state is maintained until temperature rise approximately stops. FIG. 25 shows a result of temperature rise in upper and lower parts of the power module.

As shown in FIG. 25, after the operation for about 15 minutes, the temperature in the lower part of the power module is increased to about 50° C. Meanwhile, the temperature in the upper part of the power module is increased to about 70° C. Considering that the initial temperature is about 25° C., the temperature rise in the upper part of the power module is about twice that in the lower part after the operation for about 15 minutes. As a result, it is found out that the temperature rise of the power module can be suppressed by disposing the low voltage unit of the booster below the high voltage unit thereof.

### Eighth Embodiment

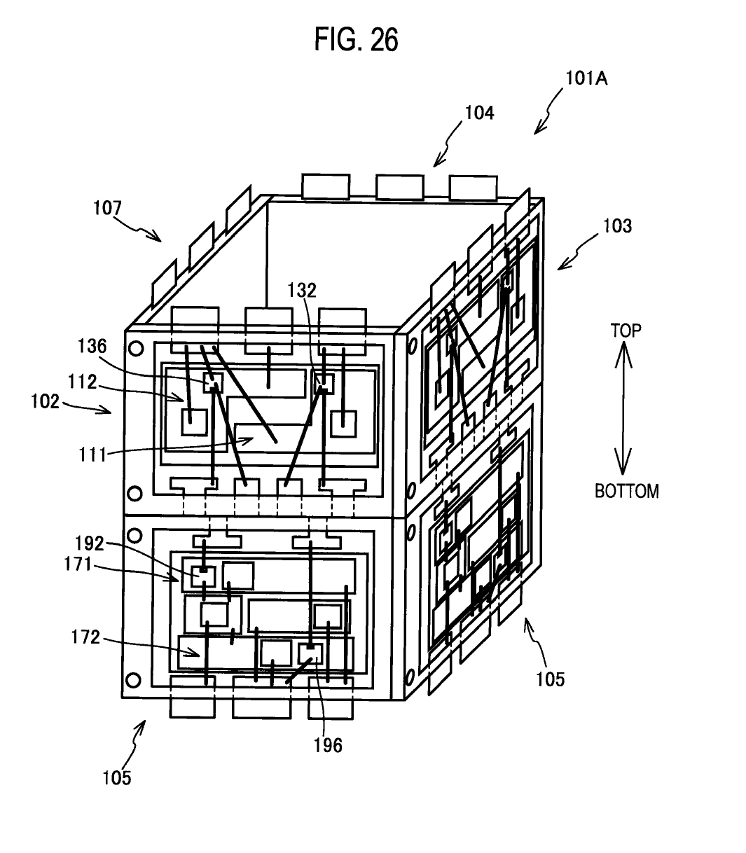

Next, with reference to the drawing, description will be given of a power module according to an eighth embodiment obtained by partially modifying the seventh embodiment described above. FIG. 26 is an overall perspective view of the power module according to the eighth embodiment. Note that the same constituent components as those of the seventh embodiment are denoted by the same reference numerals and description thereof will be omitted.

As shown in FIG. 26, a power module 101A according to the eighth embodiment is formed into a hollow rectangular parallelepiped shape. On four sides of the power module 101A, output units 102 to 104, three boosters 105 and a controller 107 are disposed.

On each of the sides, the booster 105 is disposed below each of the output units 102 to 104. Here, frequencies of switching devices 192 and 196 in the booster 105 are higher than those of switching devices 132 and 136 in the respective output units 102 to 104. Specifically, during the operation, the temperature of the booster 105 is likely to become higher than that of the output units 102 to 104. Moreover, in the booster 105, a low voltage unit 172 is disposed below a high voltage unit 171 as in the case of the seventh embodiment.

As described above, in the power module 101A according to the eighth embodiment, the booster 105, of which temperature is set higher than that of the output units 102 to 104, is disposed below the output units 102 to 104. Therefore, during the operation, the air flows from the booster 105 to the output units 102 to 104. Thus, heat generated by the output units 102 to 104 can be prevented from being transmitted to the booster 105. As a result, temperature rise of the booster 105 can be suppressed.

Although the present invention has been described in detail by use of the embodiments, the present invention is not limited to the embodiments described in this specification. The scope of the present invention is determined by description of the scope of claims and scopes equivalent to the description of the scope of claims. Hereinafter, modified embodiments obtained by partially modifying the above embodiments will be described.

For example, in the above embodiments, the description was given of the example where the present invention is applied to the three-phase IPM. However, the present invention may be applied to IPMs with two, four or more phases. Particularly, in the present invention, the IPM is formed into a three-dimensional shape. Thus, even if the number of phases is increased, an increase in a plane area can be suppressed.

Moreover, the materials, values, shapes and the like used in the above embodiments are illustrative only and can be changed accordingly.

Moreover, in the above embodiments, the respective output units are disposed on the planes of the rectangular parallelepiped or in the Z-shaped pattern. However, the output units may be disposed in other patterns. As an example, high voltage units and low voltage units of respective output units and a booster may be disposed on different sides of an octagonal column and a controller may be disposed on an upper surface thereof.

Moreover, in the above embodiments, the switching devices as semiconductor elements and the diodes are disposed on one side of the wiring board. However, the switching devices as the semiconductor elements and the diodes may be disposed separately on both sides of the wiring board.

Moreover, in the above embodiments, the cooler is an air cooling type. However, the cooler may be a water cooling type.

Moreover, in the above embodiments, one switching device is provided in each of the high voltage unit and the low voltage unit in each of the output units. However, a plurality of switching devices may be connected in parallel in each of the high voltage unit and the low voltage unit in each of the output units.

Moreover, in the above embodiments, the booster is described as an example of a voltage regulator. However, one capable of regulating a voltage is also applicable, such as a step-down unit for lowering a voltage supplied from the outside.

The materials, shapes, arrangements, values and the like related to the respective constituent components in the above embodiments can be changed accordingly.

What is claimed is:

1. A semiconductor device comprising:
a first output unit configured to output a first phase;
a second output unit configured to output a second phase different from the first phase, the second output unit being disposed on a plane intersecting with a plane having the first output unit disposed thereon; and
a controller configured to control the first and second output units.

2. The semiconductor device according to claim 1, wherein
the plane having the first output unit disposed thereon and the plane having the second output unit disposed thereon are different planes of a polyhedron.

3. The semiconductor device according to claim 2, wherein
a plane having the controller disposed thereon is any one of the planes of the polyhedron, which is different from the plane having the first output unit disposed thereon and the plane having the second output unit disposed thereon.

4. The semiconductor device according to claim 2, wherein
each of the first output unit and the second output unit includes a radiator plate, and
the first output unit and the second output unit are configured so that the radiator plates are disposed on inner sides.

5. The semiconductor device according to claim 2, wherein
each of the first output unit and the second output unit includes a radiator plate, and
the first output unit and the second output unit are configured so that the radiator plates are disposed on outer sides.

6. The semiconductor device according to claim 1, wherein
the plane having the first output unit disposed thereon and the plane having the second output unit disposed thereon are two different planes of a bent plate member.

7. The semiconductor device according to claim 1, wherein
the first output unit is provided upright on the controller.

8. The semiconductor device according to claim 7, wherein
the first output unit includes control bus bars for connection to the controller, and
the control bus bars are inserted into holes formed in the controller.

9. The semiconductor device according to claim 1, wherein
each of the first output unit and the second output unit includes a radiator plate for conducting heat in a direction different from a direction in which the controller is disposed.

10. The semiconductor device according to claim 1, wherein
each of the first output unit and the second output unit includes a first bus bar through which a current flows in a first direction and a second bus bar through which a current flows in a second direction opposite to the first direction, and
the first bus bar of the first output unit is disposed at a position closer to the second bus bar of the second output unit than the first bus bar of the second output unit.

11. The semiconductor device according to claim 1, wherein
the first output unit and the second output unit share a first bus bar through which a current flows in a first direction and also share a second bus bar through which a current flows in a second direction opposite to the first direction, and
the first bus bar and the second bus bar are stacked with an insulating member interposed therebetween.

12. The semiconductor device according to claim 1, wherein
the first output unit includes a plurality of semiconductor elements and a wiring board having the semiconductor elements provided thereon, and
the plurality of semiconductor elements are disposed on both sides of the board.

13. A semiconductor device comprising:
a plurality of output units each having switching devices and configured to output different phases, respectively;
a voltage regulator having switching devices and configured to regulate a voltage applied from the outside,
wherein
the semiconductor device is formed in a hollow structure having a plurality of sides on which the output units and the voltage regulator are disposed,
the switching devices include a first switching device to be switched on and off at a first frequency and a second switching device to be switched on and off at a second frequency higher than the first frequency, and
the second switching device is disposed upstream of the first switching device in an air flow.

14. The semiconductor device according to claim 13, wherein
the voltage regulator includes:
a high voltage unit having the first switching device; and
a low voltage unit to which a voltage lower than that applied to the high voltage unit is applied, the low voltage unit being disposed on the same side as the high voltage unit and having the second switching device.

15. The semiconductor device according to claim 13, wherein
any of the output units is disposed on the same side as the voltage regulator and has the first switching device, and
the voltage regulator has the second switching device.
